(19) United States
(12) Patent Application Publication
(10) Pub. No.: US 2010/0028534 A1
(43) Pub. Date: Feb. 4, 2010

(54) EVAPORATION UNIT, EVAPORATION METHOD, CONTROLLER FOR EVAPORATION UNIT AND THE FILM FORMING APPARATUS

(75) Inventors: Yuji ONO, Sendai City (JP); Hiroyuki IKUTA, Sendai City (JP); Yasushi YAGI, Sendai City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/511,483

(22) Filed: Jul. 29, 2009

(30) Foreign Application Priority Data
Jul. 29, 2008 (JP) 2008-195302

(51) Int. Cl. C23C 16/52; C23C 16/00; C23C 16/44

(52) U.S. Cl. 427/248.1; 118/724; 118/667

(57) ABSTRACT

In order to increase temperature controllability of a material container, an evaporation unit for forming a film includes a material supply mechanism having a material container, an outer case having a hollow interior in which the material supply mechanism is detachably secured, an internal heater provided in the material supply mechanism and heating the material supply mechanism, and a transfer path which is formed by securing the material supply mechanism to the outer case and which transfers the film forming material vaporized by heating the inner heater.

### CROSS-REFERENCE TO RELATED PATENT APPLICATIONS

This application claims the benefit of Japanese Patent Application No. 2008-195302, filed on Jul. 29, 2008, in the Japan Patent Office, the disclosure of which is incorporated herein in its entirety by reference.

### BACKGROUND OF THE INVENTION

1. Field of the Invention

The present invention relates to an evaporation apparatus utilized for evaporation process for forming a film on a substrate, evaporation unit, evaporation method and the controller for evaporation unit and more detail, temperature control to evaporate a film forming material.

2. Description of the Related Art

In recent years, an organic electroluminescent (OEL) display utilizing an organic electroluminescent device has been attracted much attention. As organic electroluminescent (OEL) has some advantageous features such as self-luminescent, quick responsiveness and lower power consumption, it does not need backlight to display. So it can be a promising display device, for example, portable display devices.

As shown in the FIG. 3, organic electroluminescent device is formed on a glass substrate, and organic layer is interleaved by anode and cathode layer. When an electric voltage is applied to anode and cathode layer, hole is injected into the organic layer from anode layer and an electron is injected into the organic layer from cathode layer. Holes and electrons injected into the organic layer recombine to emit light.

In the manufacturing process for the organic electroluminescent device which is self-luminescent as shown above, some of organic materials are evaporated to form the organic layers. In evaporating processes, temperature control dominates an evaporation rate of the material. Then, it is important to control temperature in order to obtain a film with good film properties, improved brightness and increased device lifetime. Especially, in a case that a plurality of organic materials is intermixed while supplying them through supply line to deposit an organic layer on a substrate, a mixing rate being dependent to evaporation speeds is influential to film properties. Therefore the temperature control within ±0.1 degree Celsius is required.

For instance, in temperature control method shown in patent document 1, material container is heated by an outer heater installed outside of the material source to a predetermined temperature, so that vaporizing rate of the organic material can be controlled. Vaporized organic material is transferred by a carrier gas to deposit an organic film on the substrate.

When thinking of maintenance for replenishing material into material container, generally, an evaporation source is relatively large, and thereby a location at which the heater is installed should be structured separately with the material container. In doing so, it is easier to handle the material container with the heater left when replenishing the material.

Patent document No. 1: Japanese Patent Laid-open Publication 2004-220852

However, as the material container and heater installation member is separately structured, there is a space between the material container and heater installation member to cause contact heat resistance. Especially, since an evaporation source is evacuated, the space is in vacuum, so contact heat resistance becomes greater and heat transfer between them becomes small.

Therefore, so as to control the temperature of the material container to a predetermined value, a temperature sensor is disposed at a heater installation member side. And even though the heater is controlled based on the temperature sensed by the sensor, precise temperature control is difficult. Heat is difficult to be transferred from the heater installation side to the material container due to contact heat resistance of the space.

Further, the distance between the heater and the material container is increased by the thickness of the heater installation member. So the heat resistance when the heat is transferred is greater, and heat generated in the heater is difficult to be transferred. Since the heater is disposed to surround the evaporation source, a part of heat is deprived of due to out-going radiation of the heat. Therefore, there occurs the temperature difference between the heater installation side and the material container.

On the contrary, the temperature difference is measured and output of the heater is supposed to be controlled by adding the quantity of the heat corresponding to the temperature difference. However, adjustment of the quantity to add is difficult and the accuracy is likely to be low compared to a direct temperature control.

Temperature sensor is disposed to the material container and the heater disposed at the heater installation side can also be controlled based on the direct temperature measurement of the material container. In this way, however, a portion sensed by sensor is different from the heater installation member which is controlled with respect to the temperature sensed, so the temperature control of the heater becomes difficult. As a result, the accuracy will be low. In this way, it is also difficult to enhance the temperature controllability of the material container.

From above mentioned factors, if the material container and the heater installation member are separately structured, there occurs temperature difference between the heater installation side and the material container. Initiation of the temperature change of the material container delays as the heater output is varied. So responsiveness will be low. This lowness of the temperature controllability of the material container affects film formation control and further leads to deterioration of the film property.

To solve above mentioned problems, the present invention provides the evaporation unit, evaporation method and controller for evaporation unit and evaporation apparatus, where the temperature controllability of material container is improved.

### SUMMARY OF THE INVENTION

To solve the above described problem, according to the embodiment of the present invention, there is provided an evaporation unit, the unit comprising: a material supply mechanism having a material container containing a film forming material therein; an outer case having a hollow interior in which the material container detachably secured; a first heating element provided in the material supply mechanism and directly heating the material container; and a transfer path which is formed by securing the material supply mechanism to the outer case and transfers the film forming materials vaporized by heating the first heating element, the film forming material being stored in the material container.

For example, the first heating element is disposed at a material supply side and heat the material container directly. Also, for example, when the first heating element is a heater, a member in which the heater is installed and an object to be heated are the same material supply mechanism. Therefore there is no contact heat resistance while heat is transferred to the material container.

In addition, as the distance from the heater to the material container becomes short, heat resistance and heat radiation as a whole is small when heat from the heater is transferred to the material container. So, heat from the heater is sufficiently transferred to the material container and heat responsiveness becomes better, in other words, temperature change is initiated shortly after heat is transferred to the material container and heater output is altered. Consequently, temperature controllability of the material container can be improved and film forming controllability can also be improved. As a result, a film with good property may be formed by evaporated film forming material by heating.

“Evaporation” means not only a phase transition from liquid to gas but from solid to gas directly without going through liquid phase, that is, sublimation.

The material supply mechanism further includes a supply line for introducing carrier gas and the first heating element may be disposed to contact or embedded in at least one of the material container and the supply line.

In this way, since there occurs no contact heat resistance when heat from the first heating element is transferred to the material container, efficient heat transfer is realized. In addition, heat radiation from the carrier gas introducing side at an outer case may be efficiently prevented.

Then, as temperature of the material container responds timely corresponding to temperature adjustment of the first heating element, film forming controllability becomes better and the film with good film property may be obtained.

A first temperature sensor may be additionally disposed on the material supply mechanism and the first heating element may be controlled based on a temperature sensed by the first temperature sensor.

The first temperature sensor and the first heating element are disposed in the material container. So, when controlling the first heating element based on the temperature sensed by the first temperature sensor, there is no need to adjust the heater output by adding the quantity of the heat corresponding to the temperature difference due to contact heat resistance. Therefore, temperature controllability of the material container will be better, which leads to an enhancement of film forming controllability and to obtain a film with good film properties.

There may be provided a second heating element disposed on the outer case and heating the material container indirectly via the outer case, and a second temperature sensor equipped with the outer case. The second heating element may be controlled based on a temperature sensed by the second temperature sensor.

Using the first and second heating elements may prevent temperature variation of the evaporation unit as a whole and then temperature controllability of the material container may be improved.

The first heating element may heat the material container inserted into the outer case, or may heat the material container and the supply line for carrier gas are inserted into the outer case all together.

The first heating element and the material supply mechanism may be detachably secured to the outer case.

As the first heating element and material supply mechanism can be detached from the outer case, maintenance may be easier when replenishing film forming material.

Furthermore, to solve the above mentioned problem, according to the other embodiment of the present invention, the method of evaporating the material is provided. The method comprising: securing a material supply mechanism having the material container detachably into a hollow outer case; sensing the temperature of the material supply mechanism by the first temperature sensor disposed on the material supply mechanism; heating the material container directly by controlling the first heating element disposed on the material supply mechanism based on the sensed temperature of the material supply mechanism; and transferring the film forming material vaporized by heating the first heating element, the film forming material being stored in the material container, through the transfer path formed by the material supply mechanism and the outer case.

The temperature of the outer case may be sensed by a second temperature sensor disposed on the outer case and the second heating element disposed to the outer case may be controlled to indirectly heat the material container based on the sensed temperature of the outer case.

To solve the above mentioned problem, according to the other embodiment, there may be provided a controller for controlling the evaporation unit, wherein a temperature sensed by the first temperature sensor is taken in at every predetermined time interval and the first heating element is controlled based on the temperature.

To solve the above described problem, according to another embodiment, there may be provided a film forming apparatus wherein the film forming material is vaporized by heating the first heating element disposed to the evaporation unit and the vaporized film forming material is transferred through the transfer path and is deposited on the object to be processed.

A plurality of evaporation units are provided and connected to primary transfer path respectively. Vapor of film forming material vaporized in respective evaporation unit is transferred through transfer path to the primary transfer and is deposited on the object to be processed while being mixed in the primary transfer path.

In this way, a plurality of film forming materials is evaporated in a plurality of evaporation units and can be transferred to the object to be processed while being mixed in the primary transfer path. When using above described evaporation unit, no contact heat resistance Rb occurs and heat resistance Rt becomes small, and thus precise temperature control of the material container is realized and vaporization rate (corresponding to the film forming rate) in each evaporation unit can be precisely controlled. So, it can be possible to control the mixing ratio of more than one film forming material precisely, and thus a film with good property can be formed on the object to be processed. Consequently, for example, brightness may be improved and life time of the device may become longer when talking about the organic electroluminescent device.

### BRIEF DESCRIPTION OF THE DRAWINGS

The above and other features and advantages of the present invention will become more apparent by describing in detail exemplary embodiments thereof with reference to the attached drawings in which:

FIG. 1 is an overview structure of a cluster type substrate processing apparatus of each embodiment of the present invention;

FIG. 2 is a schematic view of an evaporation mechanism of the same embodiment;

FIG. 3 is a view of a structure of an organic electroluminescent device fabricated by the film forming apparatus of the same embodiment;

FIG. 4 is a longitudinal sectional view of an evaporation unit of the first embodiment;

FIG. 5 is a perspective view of the outer case and the material supply mechanism of the first embodiment;

FIG. 6 is an explanatory drawing of contact heat resistance;

FIG. 7 is a flow chart of the temperature control process;

FIG. 8 is a graph showing the correlation between sensed temperature Ta, Tb and set temperature of the material container;

FIG. 9 is a longitudinal sectional view of the evaporation unit of the second embodiment;

FIG. 10 is a perspective view of the outer case and the material supply mechanism of the second embodiment;

FIG. 11 is a longitudinal sectional view of the evaporation unit for comparison;

FIG. 12 is a perspective view of the outer case and the material supply mechanism for comparison;

FIG. 13 is an experimental result of the temperature control using the evaporation unit of the second embodiment;

FIG. 14 is an experimental result of the temperature control using the evaporation unit of comparative example.

### DETAILED DESCRIPTION OF THE INVENTION

Referring to the drawings attached, one embodiment of the invention is explained in detail. Explanation of the elements with substantially same functions and structures are omitted by indicating the same numerals.

### The First Embodiment

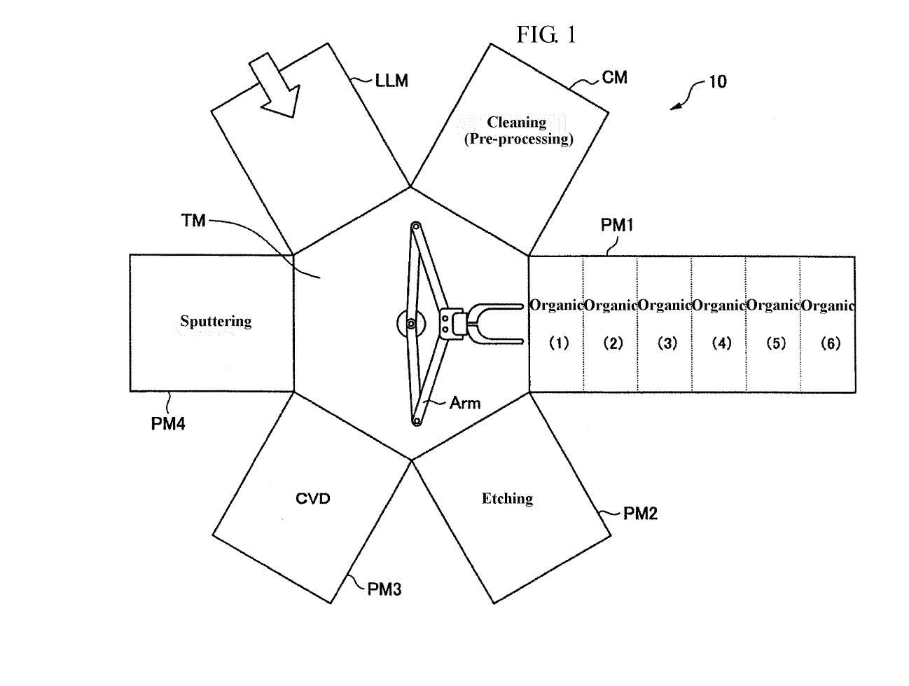

At first a substrate processing system utilizing an evaporation unit will be explained referring to FIG. 1, before explaining the evaporation unit of the first embodiment.

(Substrate Processing System)

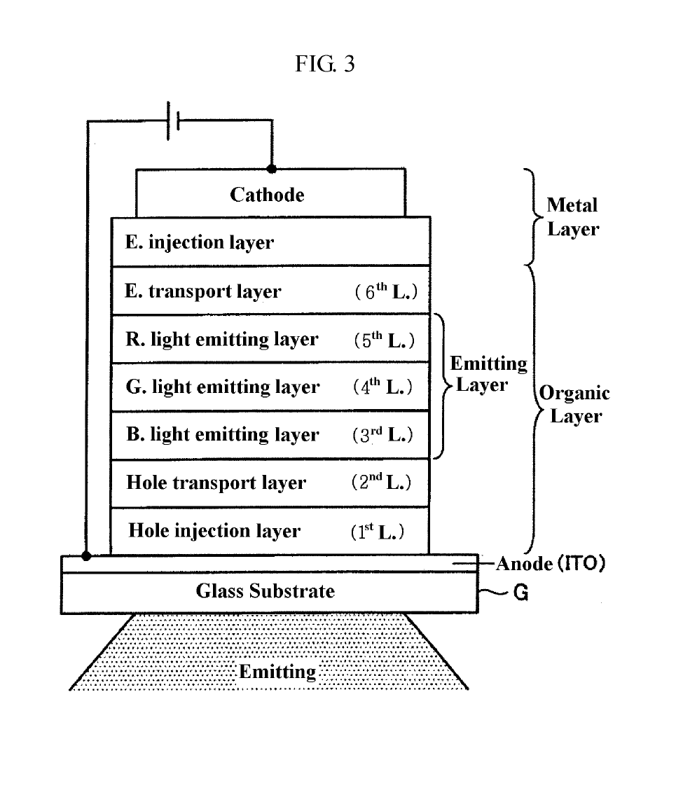

A substrate processing system 10 of the first embodiment is cluster type apparatus with plurality of processing chamber comprising a load lock chamber (LLM), transfer chamber (TM), pre-processing chamber (CM), and four process modules (PM1-PM4). The substrate processing system is used for, for example, manufacturing an electroluminescent device as in FIG. 3.

Inside of the load lock chamber (LLM) is maintained in a vacuum state when a glass substrate has been transferred into the load lock chamber so as to transfer the substrate to the processing module which is kept in a high vacuum. Indium Tin Oxide (ITO) as an anode electrode is formed in advance on the glass substrate G. The substrate G is transferred into pre-processing chamber (CM) by a transfer arm (Arm) in the transfer chamber (TM). After the surface of the substrate (ITO surface) is cleaned, the substrate is transferred into a processing module (PM1).

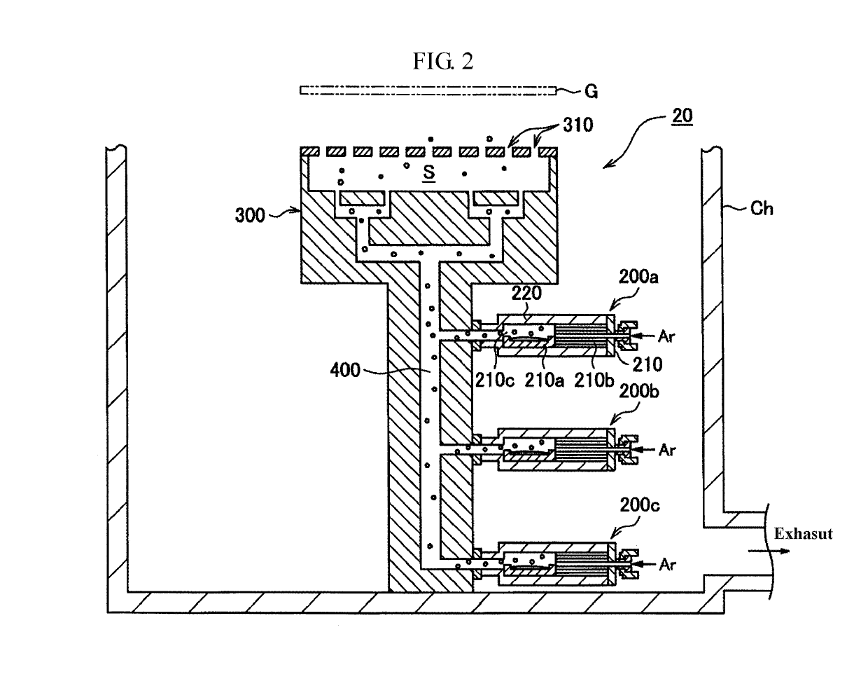

Six evaporation mechanisms 20 of FIG. 2 are arranged in linear shape in the processing module PM1. Six organic layers are formed on ITO successively. After the film forming, the substrate G is transferred into a processing module PM4 to deposit a metal electrode (cathode layer) on the organic layers by sputtering. Further, the substrate G is transferred into a processing module PM2 to form a wiring pattern by etching. Then the metal wiring is formed in the pattern by sputtering in the processing module PM4 again. Finally, the substrate is transferred into processing module PM3, and an encapsulation film for sealing organic layers is deposited by CVD (chemical vapor deposition).

(Sequentially Deposition of an Organic Layer)

A mechanism for successively forming six organic layers is explained in the following. Six evaporation mechanisms 20 arranged in the processing modules PM1 all have a same structure. Accordingly, referring to a longitudinal cross-sectional view of the evaporation mechanism shown in FIG. 2, the structure of only one evaporation mechanism is explained.

The evaporation mechanism 20 is disposed inside of rectangular processing chamber Ch with other five evaporation mechanisms. Interior space of the processing chamber is kept at a desired vacuum level by an exhaust (evacuation) mechanism (not shown). The evaporation mechanism 20 has three evaporation units 200a-200c and discharge mechanism 300 which are connected to one another by a primary transfer path 400.

The evaporation unit comprises a material supply mechanism 210 and an outer case 220. The material supply mechanism 210 comprises a material container 210a for storing a film forming material and a transfer path 210b for introducing carrier gas. The outer case 220 is formed in a bottle shape and the material supply mechanism 210 is detachably secured in a hollow interior of the outer case 220. When the material supply mechanism 210 is secured to the outer case 220, a transfer path 210c for transferring vaporized molecules of an organic film forming material is formed.

A gas supply source (not shown) is connected to an edge of the material supply mechanism to supply Argon gas from the gas supply source to the transfer path 210b. Argon gas can function as a carrier gas to transfer molecules of the organic material stored in the material container 210a. Carrier gas is not limited to Argon gas. Other inert gas such as Helium gas or Krypton gas is possible.

Organic molecules of the film forming material are transferred from the transfer path 210c of the evaporation unit 200 to the discharge mechanism 300 via the primary transfer path 400 and discharged through openings 310 out of the discharge mechanism 300 after staying temporarily in a buffer space S. Then the film is formed on the substrate G right above the discharge mechanism 300.

The result of sequential film forming using six evaporation mechanisms 20 is shown in FIG. 3. According to FIG. 3, while the substrate G is transferred over the discharge mechanism 300 of the 1^{st} through 6^{th} evaporation mechanisms at a predetermined speed, a hole injection layer as a first layer, a hole transport layer as a second layer, a blue light emitting layer as a third layer, a green light emitting layer as a forth layer, a red light emitting layer as a fifth layer, and an electron transport layer as a sixth layer are formed sequentially on ITO of the substrate G. In the blue light emitting layer, the green light emitting layer and the red light emitting layer, holes and electrons recombine to emit light. Metal layer (Ag layer) on the organic layers is, as described above, formed by sputtering in the processing module PM4 in the substrate processing system 10.

(Inner Structure of the Evaporation Unit)

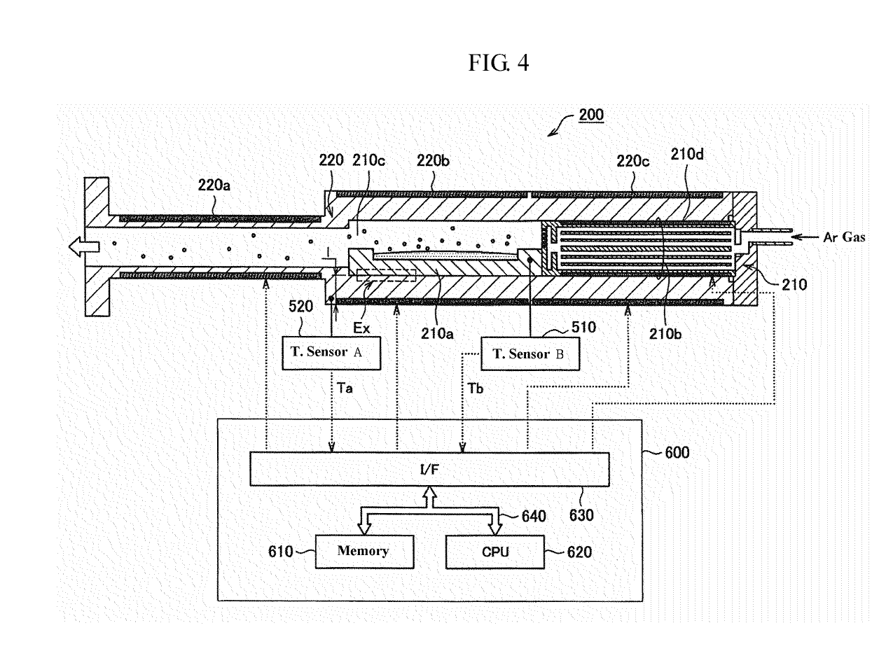

Next, the inner structure of the evaporation unit 200 provided in the evaporation mechanism 20 of the present embodiment is explained referring to the cross-sectional view of the evaporation unit 200 in FIG. 4.

The material supply mechanism 210 and the outer case 220 in the evaporation unit 200 may be made of same kind of material, stainless steel. Therefore, thermal conductivity lambda of the material container 210a of the material supply mechanism 210, transfer path 210b of carrier gas and the outer case 220 are the same. The material supply mechanism 210 is inserted into the bottle-shaped outer case 220 from the opening of the bottom side (right side in FIG. 4) and is secured to the outer case 220, and inside of the outer case 220 is closed. Inside of the outer case 220 is evacuated through the opening in the front end (left side in FIG. 4) of the outer case by a pump (not shown) to maintain a predetermined pressure.

At the periphery of the outer case 220, outer heaters 220a, 220b, and 220c are wound at the same interval. Inner heater 210d is disposed in the supply line 210b of the material supply mechanism 210.

Inner heater 210d is provided in the material supply mechanism 210 and corresponds to a first heating element to heat the material supply mechanism 210, and the outer heaters 220a, 220b, and 220c correspond to a second heating element to heat the material container 210a provided on the outer case 220.

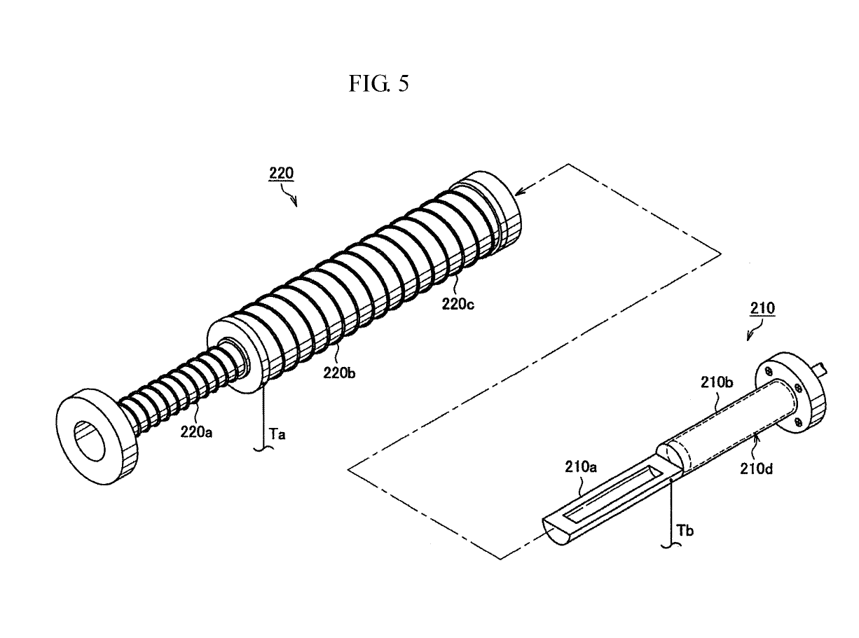

Furthermore, the inner heater 210d may be provided to contact either the material container 210a or the supply line 210b or to contact both. It may also be provided to be embedded in either the material container 210a or the supply line 210b or in both. However, the inner heater 210d needs to be provided at a preferable location, as shown in FIG. 5, where it can be removed from the outer case 220 with the material supply mechanism 210 easily when supplying film forming material with the material container 210a and inserted easily into the outer case 220 again when completing material supply. Then this enables maintenance easier.

A temperature sensor B 510 as a first temperature sensor is provided in the material supply mechanism 210. Controller 600 controls inner heater 210d based on the temperature Tb sensed by the temperature sensor B 510. A temperature sensor A 520 as a second temperature sensor is provided in the outer case 220. Outer heaters 220a, 220b, and 220c are controlled by the controller 600 based on the temperature Ta sensed by the temperature sensor A 520.

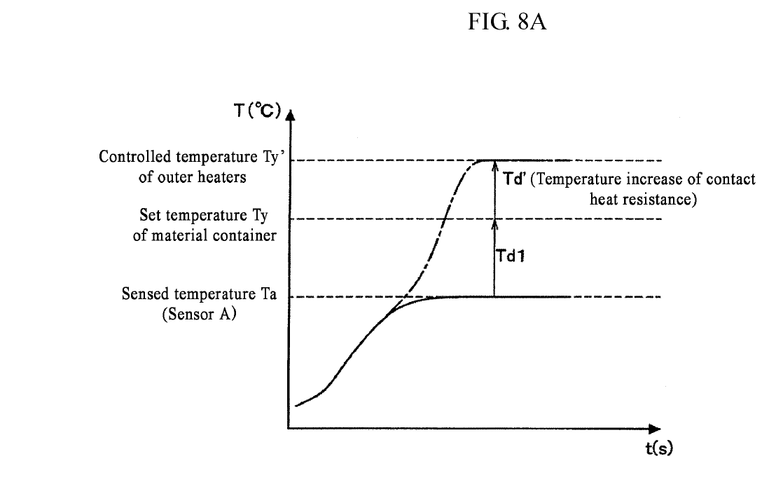

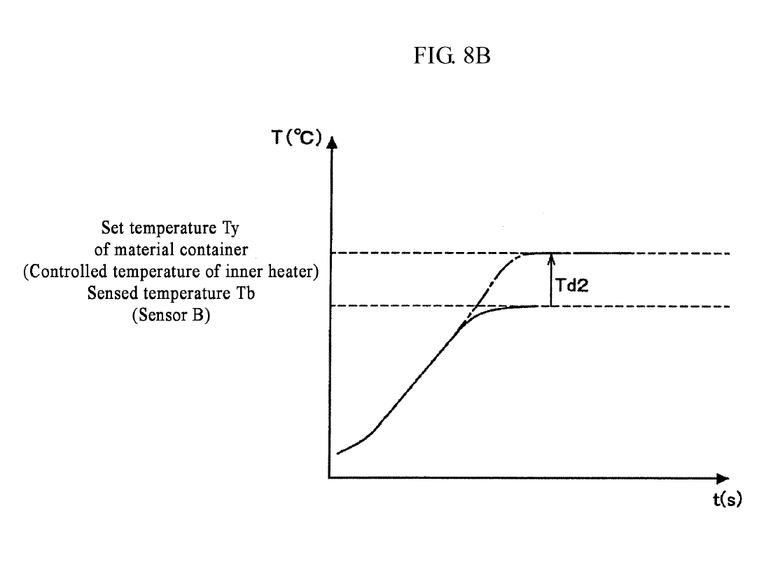

The controller 600 comprises a memory 610 such as ROM or RAM, CPU 620 which functions as a brain part in charge of various controls, and I/F 630 which functions as an input-output interface between the inside and the outside all of which are connected via a bus 640. Data, tables of FIGS. 8A and 8B and programs for executing temperature control of FIG. 7 are stored in the memory 610. CPU 620 calculates voltages to be applied to outer heaters 220a-220c and inner heater 210d using data and program stored in the memory 610 based on temperatures Ta, Tb sensed by temperature sensors. The voltages to be applied are sent to temperature controllers (not shown) and the temperature controllers apply the voltages to the outer heater 220a-220c and the inner heater 210d, based on received information of voltages, respectively. Thereby the material container 210a is maintained at a predetermined temperature and vaporization speed of the film forming material is controlled.

Vaporization means not only a phenomenon that liquid phase changes to gas phase but a phenomenon that solid phase changes to gas phase directly without going through liquid phase. Temperature control by controller 600 is further described later.

(Heat Transfer)

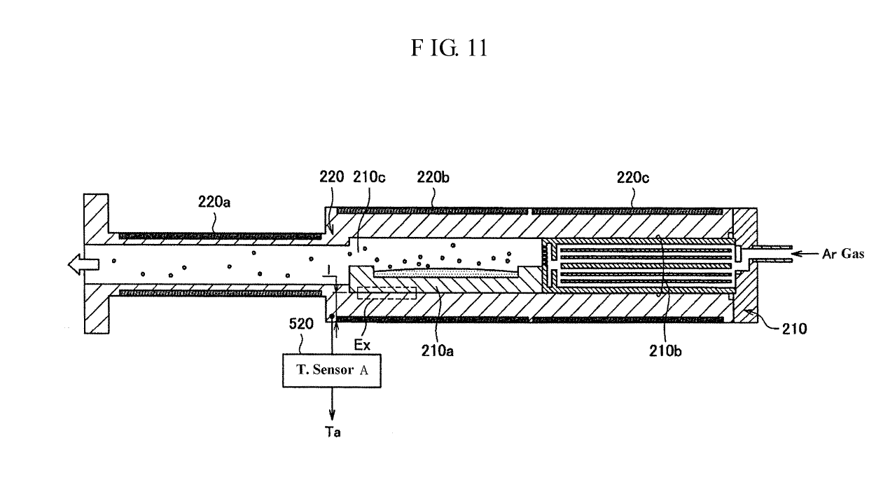

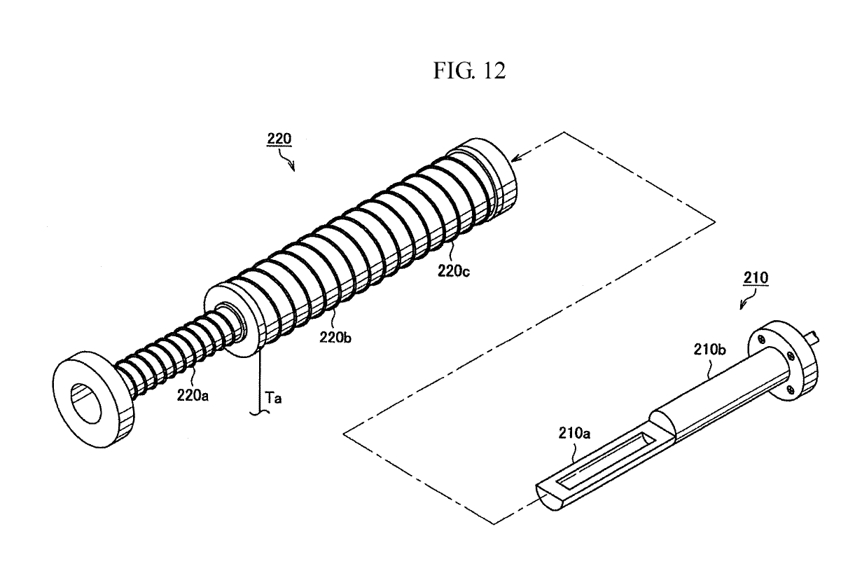

As explained above, in the evaporation unit 200 according to the embodiment of the invention, the outer heaters 220a-220c is provided in the outer case 220 and the inner heater 210d is also provided in the material supply mechanism 210. The difference of the heat transfer between two cases is explained; (1) heater is provided at the material supply mechanism side of the evaporation unit 200 (FIGS. 4 and 5) and (2) heater is not provided (FIG. 11, 12).

First of all, as shown in FIG. 11, 12, heat transfer is explained in a case that the outer heaters 220a-220c are provided only in the outer case 220 and there is no inner heater corresponding to the inner heater 210d shown in FIG. 4.

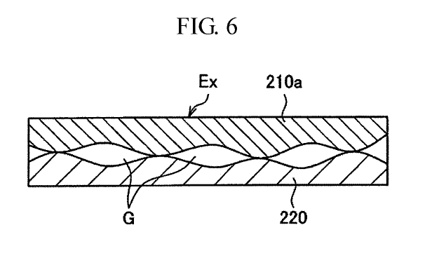

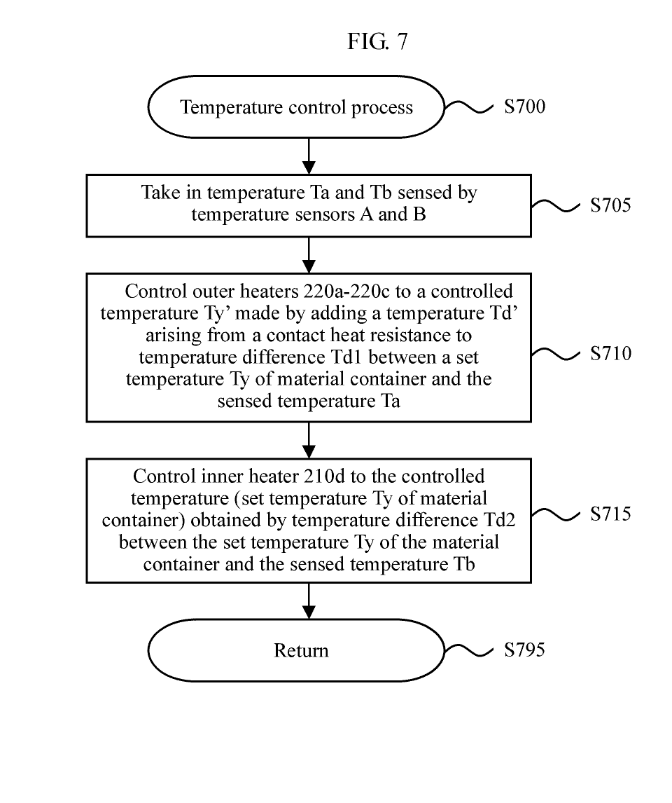

There is a gap at a contact surface between the outer case 220 and the material container 210a as shown in FIG. 6 which is a magnified view of an area Ex in FIG. 11. Thus, heat generated in the outer heaters 220a-220c is transmitted to the outer case 220, to the gap G of the contact surface between the outer case 220 and the material supply mechanism 210, and to the material container 210a. Heat resistance Ra, Rb and Rc will occur at the outer case 220, the gap G of the contact surface and the material container 210a, respectively.

Among these heat resistances, the main factor to deteriorate the heat transfer is the heat resistance Rb arising at the gap G of the contact surface between the material supply mechanism 210 and the outer case 220. Especially, inside of the evaporation unit is kept in vacuum state. As the gap G also exists in the vacuum, contact heat resistance is large and heat transfer rate is low.

Therefore, to control the material container 210a at a desired temperature, a temperature sensor A is disposed on the outer case side. But heat of the outer heaters 220a-220c is difficult to be transferred from the outer case to the material container due to the contact heat resistance Rb when the heat is transferred in the gap G of the contact surface, even though output of the outer heaters 220a-220c is controlled based on the temperature Ta sensed by temperature sensor A.

Second factor to deteriorate heat transfer is heat resistance Ra at the outer case 220 and Rc at the material supply mechanism 210. Heat resistance Ra (or Rc) is derived of the equation below.

Heat resistance Ra (or Rc)=l/(lambda×A)

Here, thermal conductivity of the each element is lambda,

thickness of the each element is l, and

contact surface of each element is A.

Here, as the material of the outer case 220 and the material supply mechanism 210 is the same, thermal conductivity lambda becomes same at a certain temperature. In addition, contact surface of the outer case and the material supply mechanism is large enough. So the distance between the outer heaters 220a-220c and the material container 210a becomes longer by the thickness of the outer case 220. Therefore, heat of the outer heaters 220a-220c is difficult to be transferred to the material container 210a as heat resistance Rt (=Ra+Rc) becomes large.

Furthermore, heat is radiated from the bottom surface of the outer case (right side in FIG. 4). From a number of reasons mentioned above, enough heat is not transferred to the material container 210a from the heater with only the outer heaters 220a-220c. In addition, with only the outer heaters 220a-220c, initiation of the temperature change of the material container 210a delays as the heater output is varied. So there may occur the temperature difference between the outer heater and the material container. As precise temperature control within 0.1 degree Celsius is required in an organic film forming process, the deterioration of the temperature controllability of the material container 210a caused by the temperature difference between the outer heater and the material container affects film forming controllability and leads to deterioration of the film quality.

In contrast, temperature sensor A may be provided in the material container 210a and the outer heaters 220a-220c may be controlled based on a directly sensed temperature of the material container 210a. However, the material container 210a which is sensed by temperature sensor A and the outer case 220 in which actually controlled outer heaters 220a-220c are provided could be a different element each other, so the temperature control of the outer heaters 220a-220c considering heat resistances Ra, Rb, and Rc is difficult and the accuracy is thought to be low. Also in this way, precise temperature control (within 0.1 degree Celsius) is difficult.

Further when a process is suspended and in idle, supply of carrier gas is stopped. And a valve is shut off (not shown) not to let gas molecules flow to the primary transfer path from the outer case. Then inside of the evaporation unit is sealed. Meanwhile, inside of the evaporation unit 200 is evacuated by an exhaust apparatus. Therefore, heat transfer is even more difficult because inside of the evaporation unit 200 will be in higher vacuum state in idle than in process due to the absence of the carrier gas.

The outer heater side and the material container side tend to be heat-equilibrium. For this reason, the heat from the heater flows into the material container side to gradually increase the temperature of the evaporation unit and the film forming material. The film forming material stored in the material container 210a is exposed to high temperature to affect later processes.

To solve this problem, it is necessary to decrease temperature difference between the outer heater and the material container. As one thing to overcome the problem, heat radiation may be suppressed and additional heater may be provided at a predetermined position so as to decrease the temperature difference between the outer heater and the material container.

In the evaporation unit 200 in this embodiment in FIGS. 4 and 5, further to the outer heaters 220a-220c, an inner heater 210d is provided in the material supply mechanism 210 side to heat the material container 210a directly.

When heat from the inner heater 210d is transmitted to the material container 210a, contact heat resistance Rb does not occur. The distance between the inner heater 210d and the material container 210a gets smaller, and then the heat resistance Rt becomes small. Therefore, heat generated at the inner heater 210d is sufficiently transmitted to the material container 210d and the temperature of the material container 210a changes quickly after heat from the inner heater 210d output is changed.

Furthermore, as the outer heaters 220a-220c are wound to the outer case 220, there occurs heat loss by heat radiation. But the inner heater 210d can compensate for heat loss. Thereby temperature difference between the outer heater and the material container is decreased. As a result, temperature controllability of the material container 210a becomes better and then film forming controllability is also improved, so that film with good quality can be obtained by vaporized film forming material by heating. Additionally, if a diameter of the outer case is defined as Dφ, tolerance of the outer heaters 220a-220c is Dφ0-Dφ0.02 (mm).

(Temperature Control Process)

Next, as to temperature control process executed by the controller 600 is explained with reference to flowchart of the temperature control process (PID control process) shown in FIG. 7. The temperature control process shown in FIG. 7 is executed by the CPU 620 of the controller 600 at every certain time interval.

The controller 600 initiates temperature control process at step S700, temperature Ta, Tb which is sensed by temperature sensor A, B are taken in at step S705. Secondly, the controller 600 controls the outer heaters 220a-220c respectively to the controlled temperature Ty′ made by adding a temperature Td′ arising from a contact heat resistance to the temperature difference Td1 between the predetermined temperature Ty of the material container and the temperature Ta sensed by the temperature sensor A at step 710.

As shown in FIG. 8A, for example, the temperature of the outer heaters 220a-220c may be controlled to the temperature Ty′ made by adding the temperature difference Td1 and the temperature Td′ arising from a contact heat resistance to the present temperature.

Next, the controller 600 controls at step S715 the inner heater 210d to the temperature (set temperature Ty of the material container) obtained by the temperature difference Td2 between set temperature Ty of the material container and the temperature Tb sensed by the temperature sensor B.

As shown in FIG. 8B, the inner heater 210d is controlled to the temperature (set temperature Ty of the material container) made by adding temperature difference Td2 to the present temperature. After that whole processes are completed at step S795.

According to above described temperature control process, using the temperature sensor A and the outer heaters 220a-220c, the temperature of the material container 210a is controlled indirectly, considering contact heat resistance. Also using the temperature sensor B and the inner heater 210d, the temperature of the material container 210a is controlled directly without considering contact heat resistance. In this way, temperature controllability of the material container 210a is improved and film forming rate is kept at a desired value to obtain organic film with good film properties.

### Second Embodiment

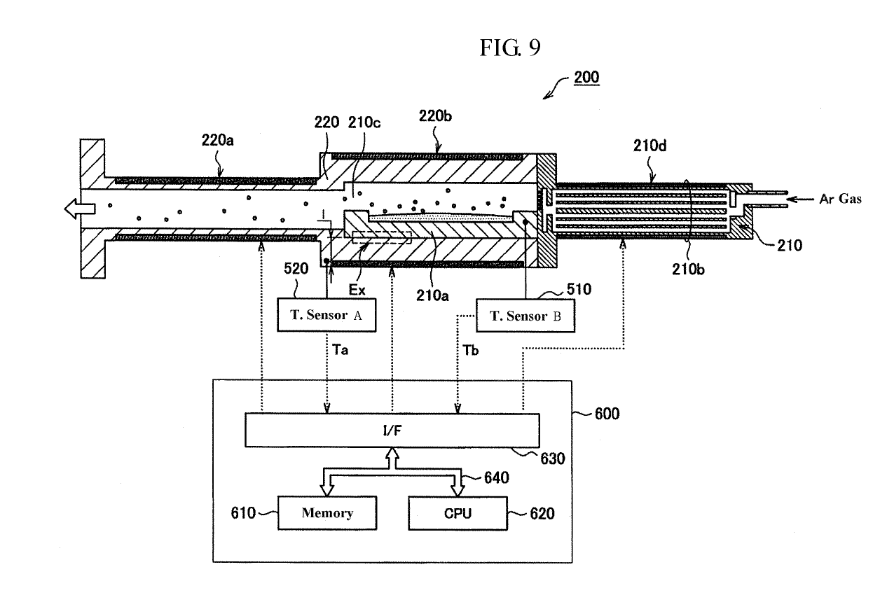

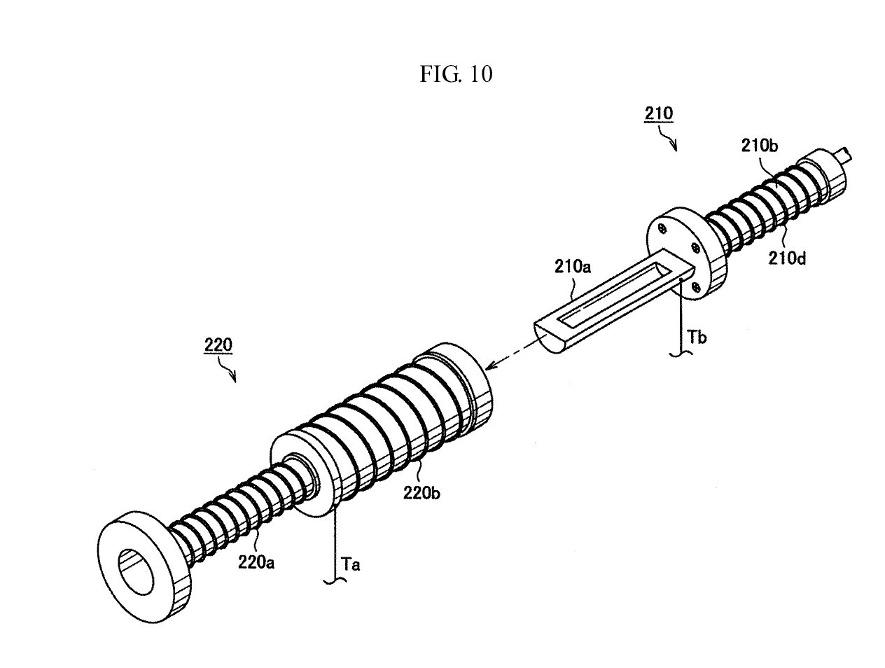

Now, an evaporation unit 200 according to the second embodiment will be described with FIGS. 9 and 10. In the evaporation unit 200 in the present embodiment, length of the outer case along the longitudinal direction is made shorter by length of an outer heater 220c provided in an outer case 220. At periphery of a supply line 210b of carrier gas, an inner heater 210d is wound as shown in FIG. 10. Thereby, in this embodiment, only the material container 210a of the material supply mechanism 210 is inserted into the outer case 220 and inside of the outer case is sealed, and gas supply line 210b is exposed to outside of the outer case 220.

Also doing this, the controller 600 takes in temperatures Ta, Tb sensed by the temperature sensors A and B to indirectly control temperature of the material container 210a by the temperature sensor A and the outer heater 220a and 220b based on the temperature control process (FIG. 7). In addition, the controller 600 directly controls the temperature of material container 210a by the temperature sensor B and the inner heater 210d. Accordingly, temperature controllability of the temperature container 210a is improved and film forming rate is maintained at the predetermined value to obtain a film with good quality.

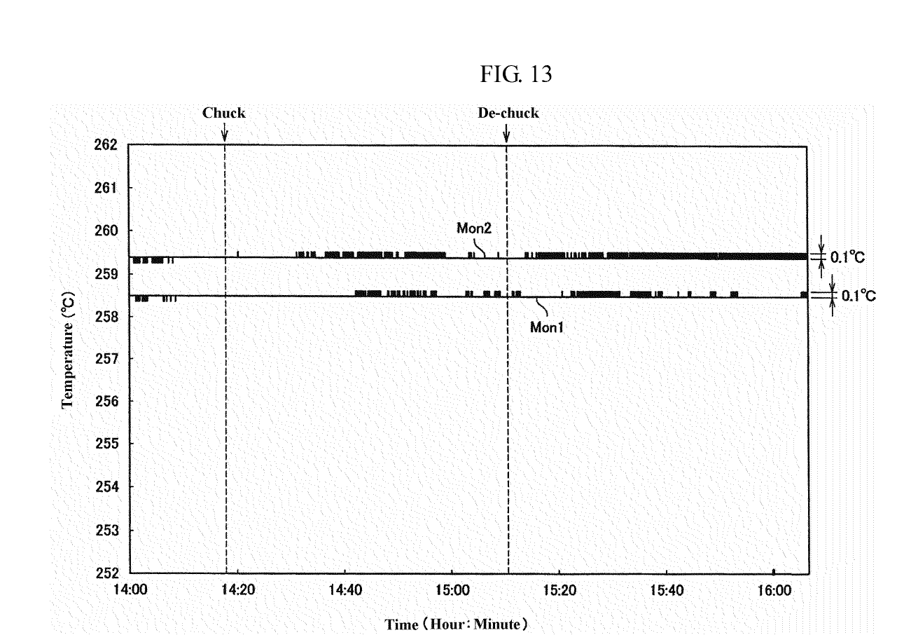

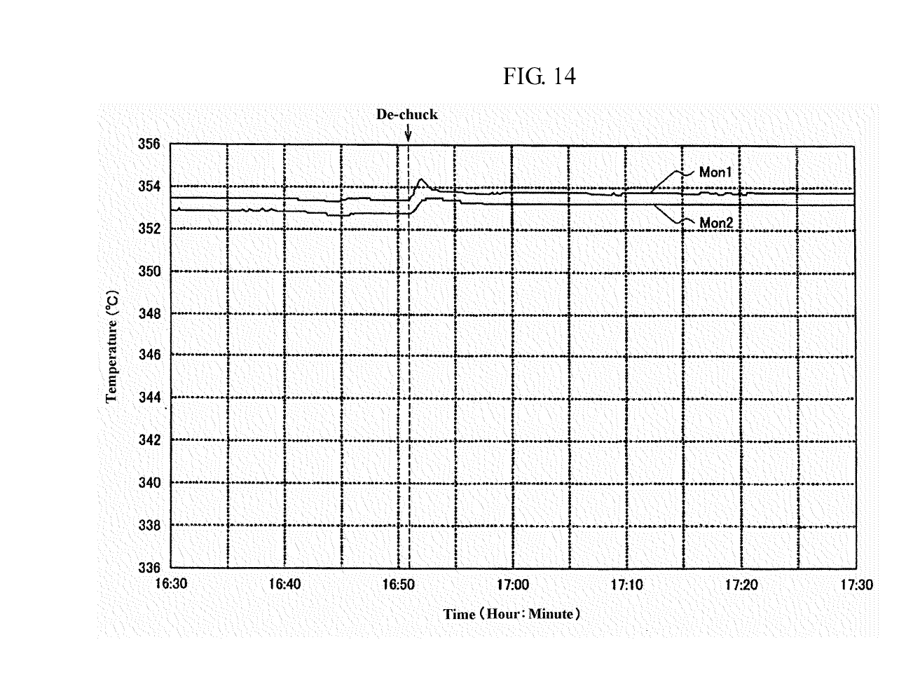

Inventors conducted experiments for the temperature controllability for two types of configurations: 1) the evaporation unit 200 with the outer heater 220a, 220b and the inner heater 210d shown in the present embodiment (FIG. 9) and 2) the evaporation unit with the outer heater 220a-220c but without the inner heater 210d shown in FIG. 11. The results are shown in FIGS. 13 and 14. FIG. 13 shows the temperature controllability for the case where the evaporation unit 200 in FIG. 9 is used. FIG. 14 shows the temperature controllability for the case where the evaporation unit in FIG. 11 is used for comparative example.

First of all, to obtain the above result, interior state of the processing chamber Ch in process is explained. The substrate G shown in FIG. 2 is held on a stage (not shown) by an electrostatic chuck (chuck). While evaporation process in progress, the substrate is cooled down by back helium as the substrate is held on the stage. When the process completed, the substrate G is released from the electrostatic chuck (de-chuck).

When de-chucking, the gas (Helium) constrained between the stage and the substrate G is released and flow into the processing chamber. So interior pressure of processing chamber Ch increases. As a result, as shown in FIG. 14, temperatures of the inside of the processing chamber (Mon1) and material (Mon2) increase by about 1 degree Celsius right after de-chucking. The controlled temperature of the outer heaters 220a-220c is changed based on the temperature Ta sensed by the temperature sensor A in FIG. 11 to recover the temperature of the inside of the processing chamber and material to a normal temperature. Experimental result in FIG. 14 shows it took five minutes until temperatures of the inside of the processing chamber (Mon1) and material (Mon2) returned to the substantially normal state. Therefore, every time de-chucking substrates, temperature inside the processing chamber is fluctuating and exerting a detrimental effect to the stability of the organic material evaporation process.

On the other hand, according to the evaporation unit 200 in the present embodiment, not only the temperature of the outer heater 220a, 220b are changed based on the temperature Ta sensed by the temperature sensor A shown in FIG. 9 but the temperature of the inner heater 210d is changed based on the temperature Tb sensed by the temperature sensor B. In the temperature control of the inner heater 210d, it is possible that temperature is controlled directly without considering contact heat resistance. Thereby, experimental result of FIG. 13 shows that the temperature is desirably controlled to maintain the temperature inside the processing chamber (Mon1) and the material (Mon2) to a value in normal state by temperature control in real time, even when the pressure inside the processing chamber increases right after de-chucking, thereby realizing temperature control better.

According to each embodiment as described above, desired heater location lowers heat resistance, and thereby the temperature controllability of the material container containing film forming material is improved. Consequently, the film forming rate can be kept at a desired value to obtain a film with good quality.

In the above embodiment, actions of each part are related each other and sequential actions as a series of actions are replaced considering the relations of each other. With replacing in this way, the embodiment of the evaporation unit can be an embodiment of an evaporation method.

Additionally, utilizing the embodiment of the above described evaporation units, a controller can be realized which controls temperature of the inner heater based on the temperature Tb sensed by the temperature sensor B taken in at every predetermined interval.

Furthermore, a plurality of the evaporation units are provided in an organic film forming apparatus and thus the organic film forming material is vaporized by the inner heater in each evaporation unit. Vaporized material is transferred to the substrate G via a transfer path, and thereby, temperature controllability of the material container is improved and mixing ratio of several kinds of film forming materials is accurately controlled and then a film with good quality is formed on the substrate G.

Preferred embodiments of the present invention are described referring to the drawings attached. It is to be understood that various changes and modifications will be apparent to those skilled in the art. Therefore, they should be construed as being included therein.

For example, in the embodiment above, the outer heaters 220a-220c are provided in the outer case side and also the inner heater 210d is provided in the material supply mechanism 210 side. However, in the evaporation unit of the present invention, a heating element is provided at the material supply mechanism side, and outer heater in the outer case side is an option.

Powder type film forming material (solid material) as an organic electroluminescent material can be used. Also, this invention can be applied to MOCVD (metal organic chemical vapor deposition) where liquid of a metal organic material is used as a film forming material and is dissociated on the substrate heated to 500 to 700 degree Celsius to deposit a film.

As explained above, according to the evaporation unit, the evaporation method, the controller for evaporation unit and film forming apparatus of the present invention, temperature controllability of the material container which contains film forming material can be improved and also the film forming rate can be maintained to the desired value to obtain a film with good quality.

What is claimed is:

1. An evaporation unit for forming a film on a substrate, the unit comprising:
a material supply mechanism having a material container containing a film forming material therein;
an outer case having a hollow interior in which the material supply mechanism is detachably secured;
a first heating element provided in the material supply mechanism and directly heating the material container; and
a transfer path which is formed by securing the material supply mechanism to the outer case and transfers the film forming material vaporized by heating the first heating element, the film forming material being stored in the material container.

2. The evaporation unit in claim 1,
wherein the material supply mechanism has a supply line for introducing carrier gas, and
wherein the first heating element is disposed to contact or embedded in at least one of the material container and the supply line.

3. The evaporation unit in claim 1, further comprising:
a first temperature sensor disposed on the material supply mechanism;
wherein the first heating element is controlled based on the temperature sensed by the first temperature sensor.

4. The evaporation unit in claim 3, further comprising:
a second heating element disposed on the outer case and heating the material container indirectly via the outer case; and
a second temperature sensor disposed at the outer case;
wherein the second heating element is controlled based on the temperature sensed by the second temperature sensor.

5. The evaporation unit in claim 2, wherein the first heating element heats the material container under state that the material container is inserted into the outer case, or state that the material container and the supply line for carrier gas are inserted into the outer case.

6. The evaporation unit in claim 1, wherein the first heating element and the material supply mechanism are secured to the outer case.

7. The evaporation unit in claim 1, wherein the first heating element is a heater.

8. An evaporating method for forming a film, the method comprising:
securing a material supply mechanism having a material container containing a film forming material detachably into a hollow outer case;
sensing a temperature of the material supply mechanism by a first temperature sensor disposed on the material supply mechanism;
heating the material container directly by controlling the first heating element disposed on the material supply mechanism based on the sensed temperature of the material supply mechanism; and
transferring the a film forming material vaporized by heating the first heating element, the film forming material being stored in the material container, through a transfer path formed by the material supply mechanism and the outer case.

9. The evaporating method in claim 8, further comprising:
sensing a temperature of the outer case by a second temperature sensor disposed on the outer case; and
heating the material container indirectly by controlling the second heating element disposed on the outer case based on the sensed temperature of the outer case.

10. A controller for the evaporation unit in claim 3, wherein a temperature sensed by the first temperature sensor is taken in at every predetermined interval and the first heating element is controlled based on the temperature.

11. A film forming apparatus for evaporating on an object to be processed with the evaporation unit in claim 1, wherein the film forming material contained in the material container is vaporized by heating the first heating element and the vaporized film forming material is transferred through the transfer path and is deposited on the object to be processed.

12. The film forming apparatus in claim 11, wherein a plurality of evaporation units are provided,
the transfer path of each evaporation unit is connected to a primary transfer path, and
each vaporized film forming material vaporized in each evaporation unit is transferred through the transfer path to the primary transfer path and is deposited on the object to be processed while being mixed in the primary transferring path to deposit on the substrate.
